(19) United States
(12) Patent Application Publication
(10) Pub. No.: US 2024/0276884 A1
(43) Pub. Date: Aug. 15, 2024

(54) PIEZOELECTRIC DEVICE, VIBRATION PANEL AND HAPTIC FEEDBACK APPARATUS

(71) Applicant: BOE Technology Group Co., Ltd., Beijing (CN)

(72) Inventors: Shuai WANG, Beijing (CN); Hui HUA, Beijing (CN); Yingzi WANG, Beijing (CN); Dongsheng HUANG, Beijing (CN); Li ZHOU, Beijing (CN)

(21) Appl. No.: 18/691,848

(22) PCT Filed: Nov. 22, 2021
(86) PCT No.: PCT/CN2021/132162

§ 371 Date: Mar. 13, 2024

(51) Int. Cl. H10N 30/50; G06F 3/01; H10N 30/87; H10N 39/00

(52) U.S. Cl. CPC H10N 30/50; H10N 30/871; H10N 30/872; H10N 39/00; G06F 3/016

(57) ABSTRACT

A piezoelectric device, a vibration panel, and a haptic feedback device. The piezoelectric device includes: at least three electrode layers stacked alternately, and a piezoelectric layer located between every two adjacent electrode layers. For all the electrode layers, the electrode layers located on the odd-numbered layers are electrically connected to each other, the electrode layers located on the even-numbered layers are electrically connected to each other, and the electrode layers located on the odd-numbered layers are insulated from the electrode layers located on the even-numbered layers.

### CROSS-REFERENCE TO RELATED APPLICATIONS

This application is a National Stage of International Application No. PCT/CN2021/132162, filed Nov. 22, 2021, which is hereby incorporated by reference in its entirety.

### TECHNICAL FIELD

The present disclosure relates to the technical field of haptic interaction, in particular to a piezoelectric device, a vibration panel and a haptic feedback apparatus.

### BACKGROUND

Haptic feedback is one of the important ways of human-computer interaction. Compared with mature audio-visual interaction technology, the haptic feedback is in a stage of rapid development. Specifically, the haptic feedback can realize texture reproduction such as material and shape, and vibration haptic feedback. The terminal integrates haptic feedback, which can improve the authenticity and immersion of human-computer interaction.

### SUMMARY

Embodiments of the present disclosure provide a piezoelectric device, a vibration panel and a haptic feedback apparatus, and the specific scheme is as follows.

An embodiment of the present disclosure provides a piezoelectric device, which includes: at least three electrode layers alternately stacked, and a piezoelectric layer between every two adjacent electrode layers;

for all the electrode layers, the electrode layers located in odd-numbered layers are electrically connected to each other, the electrode layers located in even-numbered layers are electrically connected to each other, and the electrode layers located in odd-numbered layers are insulated from the electrode layers located in even-numbered layers.

In a possible implementation manner, the above piezoelectric device provided by the embodiments of the present disclosure further includes a first conductive part and a second conductive part extending along a thickness direction of the piezoelectric device, the first conductive part and the second conductive part are arranged on opposite sides of the piezoelectric layer;

the electrode layers located in odd-numbered layers are electrically connected through the first conductive part, and the electrode layers located in even-numbered layers are electrically connected through the second conductive part.

In a possible implementation manner, in the above piezoelectric device provided by the embodiments of the present disclosure, the electrode layers located in odd-numbered layers and the second conductive part have a first gap therebetween, and the electrode layers located in even-numbered layers and the first conductive part have a second gap therebetween;

the piezoelectric device further includes: a first isolation part filled in the first gap, and a second isolation part filled in the second gap.

In a possible implementation manner, in the above piezoelectric device provided by the embodiments of the present disclosure, materials of the first isolation part and the second isolation part are the same as that of the piezoelectric layer, and each piezoelectric layer is sequentially connected in series through the first isolation part and the second isolation part.

In a possible implementation manner, in the above piezoelectric device provided by the embodiments of the present disclosure, the total number of the electrode layers and the piezoelectric layers are 5 to 21 layers.

In a possible implementation manner, in the above piezoelectric device provided by the embodiments of the present disclosure, each of the electrode layers has approximately the same thickness, and each of the piezoelectric layers has approximately the same thickness.

In a possible implementation manner, in the above piezoelectric device provided by the embodiments of the present disclosure, a thickness of each electrode layer ranges from 100 nm to 200 nm, and a thickness of each piezoelectric layer ranges from 1.5 μm to 2 μm.

Correspondingly, an embodiment of the present disclosure further provides a vibration panel, including the piezoelectric device described in any one of the above embodiments.

In a possible implementation manner, the above vibration panel provided by the embodiments of the present disclosure further includes: a first signal line electrically connected to a first conductive part, and a second signal line electrically connected to a second conductive part;

the first signal line and the second signal line are arranged in the same layer as a bottommost electrode layer;

or, the first signal line is arranged in the same layer as a bottommost electrode layer, and the second signal line is arranged in a different layer from the bottommost electrode layer.

In a possible implementation manner, in the above vibration panel provided by the embodiments of the present disclosure, the vibration panel includes multiple piezoelectric devices, and the multiple piezoelectric devices are distributed in an array.

In a possible implementation manner, in the above vibration panel provided by the embodiments of the present disclosure, the first conductive parts of all the piezoelectric devices are electrically connected to the same first signal line, and the second conductive parts of all the piezoelectric devices are electrically connected to the same second signal line.

In a possible implementation manner, in the above vibration panel provided by the embodiments of the present disclosure, among the piezoelectric devices located in the same column, the first conductive parts of two adjacent piezoelectric devices are electrically connected through a third conductive part, and the third conductive part is arranged in the same layer as a bottommost electrode layer.

In a possible implementation manner, in the above vibration panel provided by the embodiments of the present disclosure, among the piezoelectric devices located in the same column, the second conductive parts of two adjacent piezoelectric devices are electrically connected through a fourth conductive part, and the fourth conductive part is arranged in the same layer as the bottommost electrode layer.

In a possible implementation manner, in the above vibration panel provided by the embodiments of the present disclosure, each piezoelectric layer only exposes the first conductive part, the second conductive part, the third conductive part, the fourth conductive part, the first signal line and the second signal line.

In a possible implementation manner, in the above vibration panel provided by the embodiments of the present disclosure, the first conductive parts of each piezoelectric device are electrically connected to first signal lines that are independent of each other, and the second conductive parts of each piezoelectric device are electrically connected to second signal lines that are independent of each other.

In a possible implementation manner, in the above vibration panel provided by the embodiments of the present disclosure, each piezoelectric layer only exposes the first conductive part, the second conductive part, the first signal line and the the second signal line.

In a possible implementation manner, in the above vibration panel provided by the embodiments of the present disclosure, the first signal line and the second signal line are located on opposite sides of the piezoelectric devices distributed in an array.

Correspondingly, an embodiment of the present disclosure further provides a haptic feedback apparatus, including the vibration panel described in any one of the foregoing embodiments of the present disclosure.

### BRIEF DESCRIPTION OF FIGURES

FIG. 1 is a schematic diagram of a relationship between an electric field and a vibration displacement;

FIG. 2 is a schematic structural diagram of a piezoelectric device provided in the related art;

FIG. 3 is a schematic structural diagram of a piezoelectric device provided by an embodiment of the present disclosure;

FIG. 4 is a schematic top view of a dotted box AA in FIG. 3;

FIG. 5A is a schematic top view of a layer of a piezoelectric device during manufacture;

FIG. 5B is a schematic top view of another layer of a piezoelectric device during manufacture;

FIG. 5C is a schematic top view of yet another layer of a piezoelectric device during manufacture;

FIG. 6 is a schematic top view of the bottommost electrode layer of a vibration panel provided by an embodiment of the present disclosure;

FIG. 7 is a schematic top view of the bottommost electrode layer and part of a piezoelectric layer of a vibration panel provided by an embodiment of the present disclosure;

FIG. 8 is another schematic top view of the bottommost electrode layer of a vibration panel provided by an embodiment of the present disclosure;

FIG. 9 is a schematic top view of an electrode layer on the bottommost electrode layer of a vibration panel provided by an embodiment of the present disclosure.

### DETAILED DESCRIPTION

In order to make the purpose, technical solutions and advantages of the embodiments of the present disclosure clearer, the technical solutions of the embodiments of the present disclosure will be clearly and completely described below in conjunction with the accompanying drawings of the embodiments of the present disclosure. Apparently, the described embodiments are some but not all of the embodiments of the present disclosure. And in the case of no conflict, the embodiments in the present disclosure and the features in the embodiments can be combined with each other. Based on the described embodiments of the present disclosure, all other embodiments obtained by persons of ordinary skill in the art without creative effort fall within the protection scope of the present disclosure.

Unless otherwise defined, the technical terms or scientific terms used in the present disclosure shall have the usual meanings understood by those skilled in the art to which the present disclosure belongs. The words “comprise” or “include” and similar words used in the present disclosure mean that the elements or things appearing before the word include the elements or things listed after the word and their equivalents, without excluding other elements or things. Words such as “connected to” or “connected with” are not limited to physical or mechanical connections, but may include electrical connections, whether direct or indirect. “Inner”, “outer”, “upper”, “lower” and so on are only used to indicate relative positional relationship. When the absolute position of the described object changes, the relative positional relationship may also change accordingly.

It should be noted that the size and shape of each figure in the drawings do not reflect the true scale, but are only intended to illustrate the present disclosure. And the same or similar reference numerals represent the same or similar elements or elements having the same or similar functions throughout.

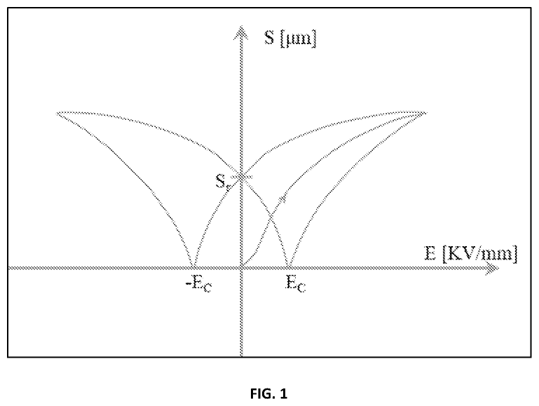

Thin-film piezoelectric materials have high dielectric constant and transparency properties, which are very suitable for screen-integrated vibrator structures. Here, lead zirconate titanate piezoelectric ceramics (PZT) are currently widely used due to their excellent piezoelectric properties. Piezoelectric materials undergo polarization deformation after an electric field is applied to generate vibration displacements, which can achieve haptic feedback effects such as force, vibration feedback, and texture reproduction. In order to increase the intensity of haptic feedback, the thickness of the piezoelectric material film can be selected to be increased in the process. As shown in FIG. 1, the displacement (S) generated by the polarization deformation of the piezoelectric material depends on the magnitude of the applied electric field (E) (voltage). The larger the electric field is, the greater the deformation is. However, increasing the thickness of the piezoelectric material film will lead to an increase in the driving voltage.

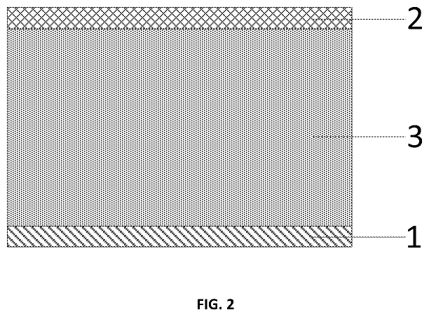

As shown in FIG. 2, a basic piezoelectric device includes: a first electrode 1 and a second electrode 2 oppositely arranged, and a piezoelectric layer 3 located between the first electrode 1 and the second electrode 2. After a voltage is applied to the first electrode 1 and the second electrode 2, the piezoelectric layer 3 is polarized to vibrate. Combining the principle shown in FIG. 1, the vibration displacement of the piezoelectric layer 3 is proportional to the magnitude of the voltage between the first electrode 1 and the second electrode 2. Therefore, in a thicker piezoelectric layer 3, the required driving voltage is very high.

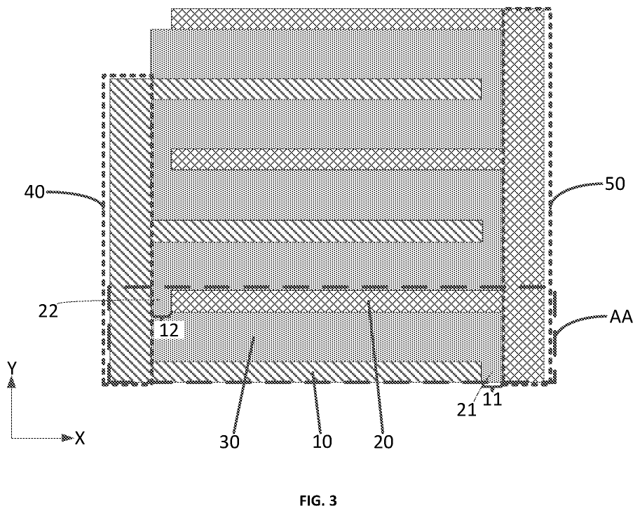

In order to solve the problem in the related art that a thicker piezoelectric layer is used to improve the intensity of haptic feedback, resulting in a high driving voltage of the piezoelectric device, an embodiment of the present disclosure provides a piezoelectric device, as shown in FIG. 3, the piezoelectric device includes: at least three electrode layers (taking 6 layers as an example, indicated by reference numerals 10 and 20), and a piezoelectric layer 30 located between every two adjacent electrode layers (10 and 20).

For all the electrode layers (10 and 20), the electrode layers 10 located in odd-numbered layers are electrically connected to each other, the electrode layers 20 located in even-numbered layers are electrically connected to each other, and the electrode layers 10 located in odd-numbered layers are insulated from the electrode layers 20 located in even-numbered layers.

The above piezoelectric device provided by the embodiments of the present disclosure is equivalent to sharing an electrode layer for inputting a first signal between two adjacent piezoelectric layers, and two voltage layers outside the two adjacent piezoelectric layers are electrically connected, to input the same second signal. In this way, the piezoelectric device is equivalent to at least two piezoelectric structures arranged in parallel, and the intensity of the haptic feedback of each piezoelectric layer in the parallel structures can be superimposed. Therefore, compared with the related art in which in order to increase the intensity of the haptic feedback, a thicker piezoelectric layer is set, which leads to the problem of high driving voltage in the related art, in the embodiments of the present disclosure, if the same intensity of the haptic feedback is needed to achieve as in the related art, the sum of the thicknesses of each piezoelectric layer is only equal to the thickness of one entire layer in the related art. For example, there are four piezoelectric layers, the corresponding input driving voltage of each piezoelectric layer can be reduced to a quarter of that in the related art. Therefore, the piezoelectric device provided by the embodiments of the present disclosure adopts at least two piezoelectric layers, and the driving voltage of the piezoelectric device can be reduced on the basis of improving the intensity of the haptic feedback of the piezoelectric device.

During specific implementation, as shown in FIG. 3, each electrode layer 10 at an odd-numbered layer may be negative, and each electrode layer 20 at an even-numbered layer may be positive. Alternatively, each electrode layer 10 at an odd-numbered layer may be positive, and each electrode layer 20 at an even-numbered layer may be negative. Specifically, the embodiments of the present disclosure will be described with an example in which the electrode layers 10 in odd-numbered layers are negative and the electrode layers 20 located in even-numbered layers are positive.

In specific implementation, in the above piezoelectric device provided by the embodiments of the present disclosure, as shown in FIG. 3, the piezoelectric device further includes a first conductive part 40 and a second conductive part 50 extending along a thickness direction Y of the piezoelectric device, and the first conductive part 40 and the second conductive part 50 are arranged on opposite sides of the piezoelectric layer 30.

The electrode layers 10 in odd-numbered layers are electrically connected through the first conductive part 40, and the electrode layers 20 in even-numbered layers are electrically connected through the second conductive part 50.

In specific implementation, in the above piezoelectric device provided by the embodiments of the present disclosure, as shown in FIG. 3, the electrode layers 10 located in odd-numbered layers and the second conductive part 50 have a first gap 11 therebetween, and the electrode layers 20 located in even-numbered layers and the first conductive part 40 have a second gap 12 therebetween.

The piezoelectric device further includes: a first isolation part 21 filled in the first gap 11, and a second isolation part 22 filled in the second gap 12. Specifically, the first isolation part 21 and the second isolation part 22 can isolate the electrode layers 10 located in odd-numbered layers from the second conductive part 50, so as to avoid short circuit between the electrode layers 10 located in odd-numbered layers and the electrode layers 20 located in even-numbered layers. When a negative signal is input to the electrode layers 10 located in odd-numbered layers and a positive signal is input to the electrode layers 20 located in even-numbered layers, the first isolation part 21 and the second isolation part 22 prevent the short circuit between the positive and negative signals.

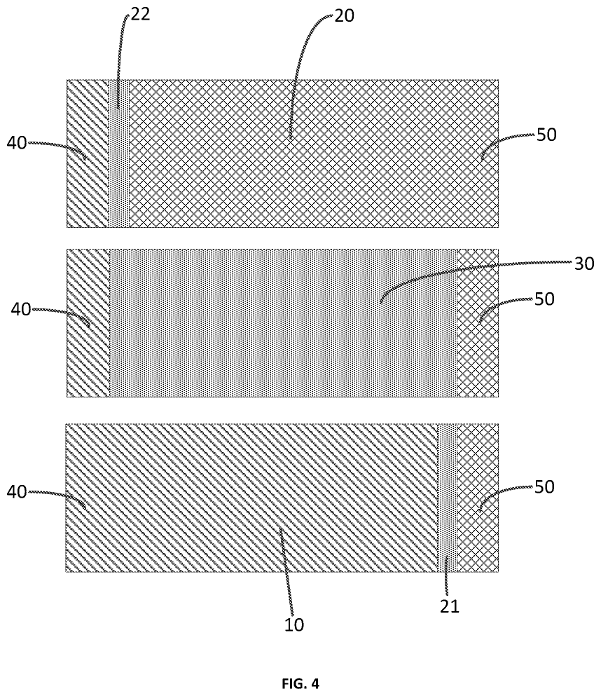

In order to better illustrate the structure of the piezoelectric device provided by the embodiments of the present disclosure, FIG. 4 shows a plan view of each layer in the horizontal dotted box AA in FIG. 3. As shown, the bottommost layer includes an electrode layer 10, a first conductive part 40, a second conductive part 50 and a first isolation part 21 for isolation; the middle layer includes a piezoelectric layer 30, a first conductive part 40 and a second conductive part 50; and the top layer includes an electrode layer 20, a first conductive part 40, a second conductive part 50 and a second isolation part 22 for isolation.

In specific implementation, in the above piezoelectric device provided by the embodiments of the present disclosure, as shown in FIG. 3, the thicknesses of the electrode layers (10 and 20) are approximately the same, and the thicknesses of the piezoelectric layers 30 are approximately the same. Specifically, the thickness of each electrode layer (10 and 20) may be 100 nm to 200 nm, and the thickness of each piezoelectric layer 30 may be 1.5 μm to 2 μm.

In specific implementation, in the above piezoelectric device provided by the embodiments of the present disclosure, as shown in FIG. 3, materials of the first isolation part 21 and the second isolation part 22 are the same as that of the piezoelectric layer 30, in this way, only the corresponding first isolation part 21 and the second isolation part 22 are filled with the piezoelectric material when the piezoelectric layer 30 is formed by using the piezoelectric material, without additional processes for separately preparing the first isolation part 21 and the second isolation part 22, which can simplify the preparation process, save production cost and improve production efficiency. The piezoelectric layers 30 are sequentially connected in series through the first isolation part 21 and the second isolation part 22, so that when a driving voltage is applied to the electrode layers 10 located in odd-numbered layers and the electrode layers 20 located in even-numbered layers, due to the embodiments of the present disclosure shown in FIG. 3 in which a thicker piezoelectric layer in the related art is divided into 5 layers, the driving voltage can be reduced to one-fifth of that in the related art, while the vibration effects of each piezoelectric layer 30 can be superimposed on each other. This can greatly reduce the driving voltage of the piezoelectric device on the basis of improving the intensity of the haptic feedback of the piezoelectric device.

In specific implementation, in the above piezoelectric device provided by the embodiments of the present disclosure, as shown in FIG. 3, the total number of the electrode layers (10 and 20) and the piezoelectric layers 30 may be 5 to 21 layers. FIG. 3 of the embodiments of the present disclosure is an example where the total number of layers is 11. Of course, the embodiments of the present disclosure do not limit the total number of the electrode layers (10 and 20) and the piezoelectric layers 30. For different stacking numbers, the principle and implementation are in the same way.

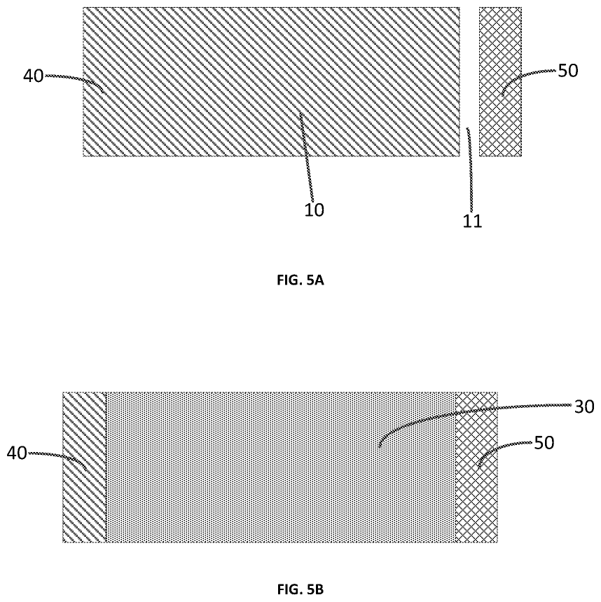

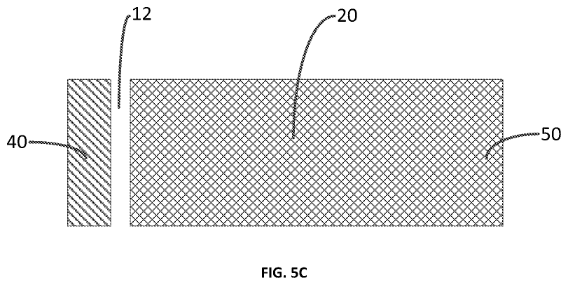

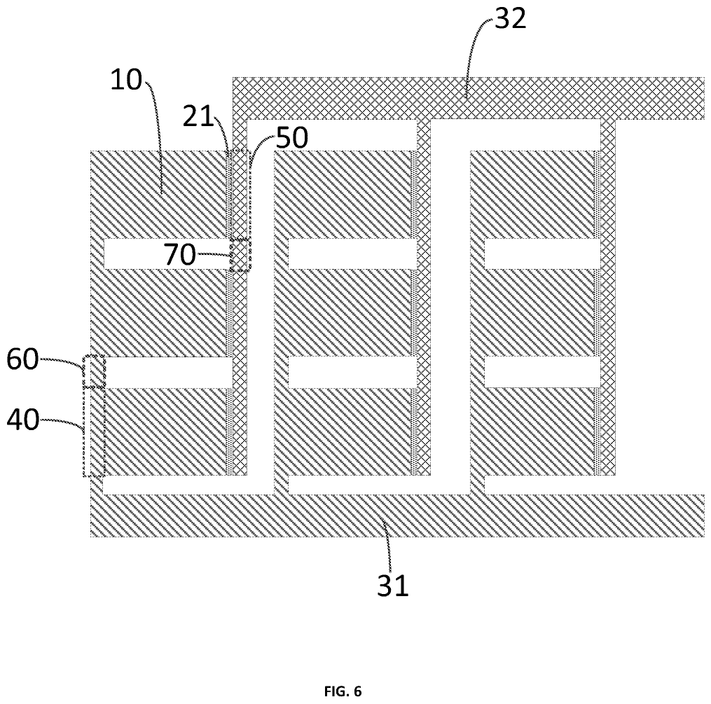

In specific implementation, for a piezoelectric device shown in FIG. 3, the manufacturing process from bottom to top may include:
1) depositing a bottommost metal layer on a glass substrate, exposing, developing and etching the metal layer to form the structure as shown in FIG. 5A, for a thickness of the entire piezoelectric device, a thickness of the deposited metal layer is generally 100 nm to 200 nm;
2) depositing a piezoelectric material film layer on the bottommost metal layer shown in FIG. 5A, and exposing, developing, and etching the piezoelectric material film layer, to stack the structure as shown in FIG. 5B on the structure as shown in FIG. 5A; and filling the first gap 11 in FIG. 5A in the piezoelectric layer 30 in FIG. 5B to form the first isolation part 21, which prevents positive and negative signals and provides insulation to prevent short circuits between the positive and negative signals;
the deposition of the piezoelectric material film layer can use magnetron sputtering or sol-gel and other technical solutions, and considering the actual process, the thickness of the deposited piezoelectric material film layer is generally 1.5 μm to 2 μm; and
3) depositing a metal layer on the stacked structure as shown in FIG. 5A and FIG. 5B, and exposing, developing, and etching the metal layer to stack the structure as shown in FIG. 5C on the structure as shown in FIG. 5A and FIG. 5B.

Next, the above steps are repeated until the piezoelectric device structure shown in FIG. 3 is formed.

In specific implementation, the above electrode layers may be made of indium tin oxide (ITO) or indium zinc oxide (IZO). Further, the electrode layers may also be made of one of titanium gold (Ti—Au) alloy, titanium Aluminum-titanium (Ti—Al—Ti) alloy, or titanium-molybdenum (Ti—Mo) alloy. In addition, the electrode layers may also be made of one of titanium (Ti), gold (Au), silver (Ag), molybdenum (Mo), copper (Cu), tungsten (W), or chromium (Cr). Those skilled in the art can set the above-mentioned electrode layers according to actual application requirements, which is not limited herein.

In specific implementation, the material of the piezoelectric layer may be one of lead zirconate titanate (Pb(Zr,Ti)O₃, PZT), aluminum nitride (AlN), zinc oxide (ZnO), barium titanate (BaTiO₃), lead titanate (PbTiO₃), potassium niobate (KNbO₃), lithium niobate (LiNbO₃), lithium tantalate (LiTaO₃), gallium lanthanum silicate (La₃Ga₅SiO₁₄). Specifically, the material for making the piezoelectric layer is selected according to the actual use of those skilled in the art, which is not limited herein. Here, when PZT is used to make the piezoelectric layer, because PZT has a high piezoelectric coefficient, the piezoelectric characteristics of the corresponding piezoelectric sensor are guaranteed, and the corresponding piezoelectric sensor can be applied to the haptic feedback apparatus, and PZT has a relatively high light transmittance, when it is integrated into a display device, it does not affect the display quality of the display device.

The above piezoelectric device provided by the embodiments of the present disclosure can be applied to the fields such as medical treatment, automotive electronics, and motion tracking systems. It is especially suitable for the field of wearable devices, monitoring and treatment outside the body or implanted in the human body, or electronic skin applied to artificial intelligence and other fields. Specifically, the piezoelectric sensor can be applied to brake pads, keyboards, mobile terminals, game handles, vehicles, and other devices that can generate vibration and mechanical characteristics.

Based on the same inventive concept, an embodiment of the present disclosure further provides a vibration panel, including any one of the above piezoelectric devices provided by the embodiments of the present disclosure. Since the problem-solving principle of the vibration panel is similar to that of the aforementioned piezoelectric device, the implementations of the vibration panel can refer to the implementations of the aforementioned piezoelectric device, and will not be repeated here.

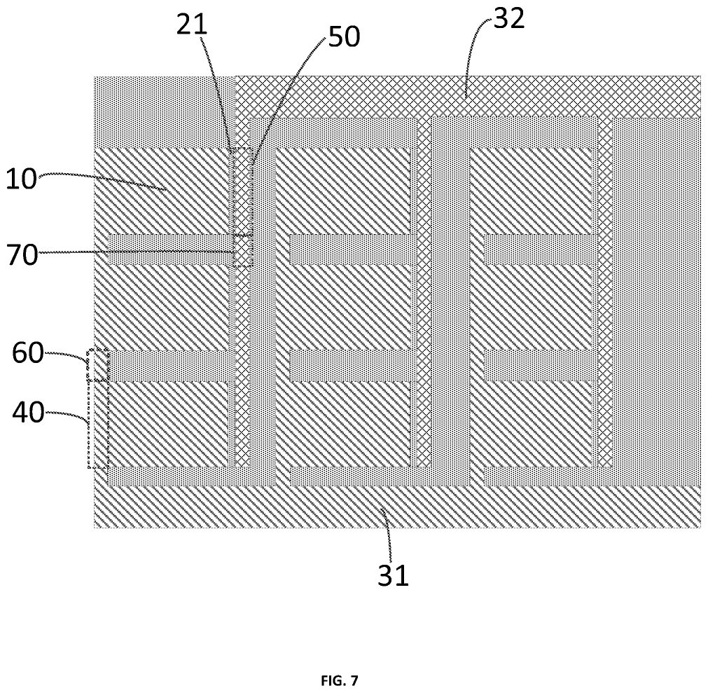

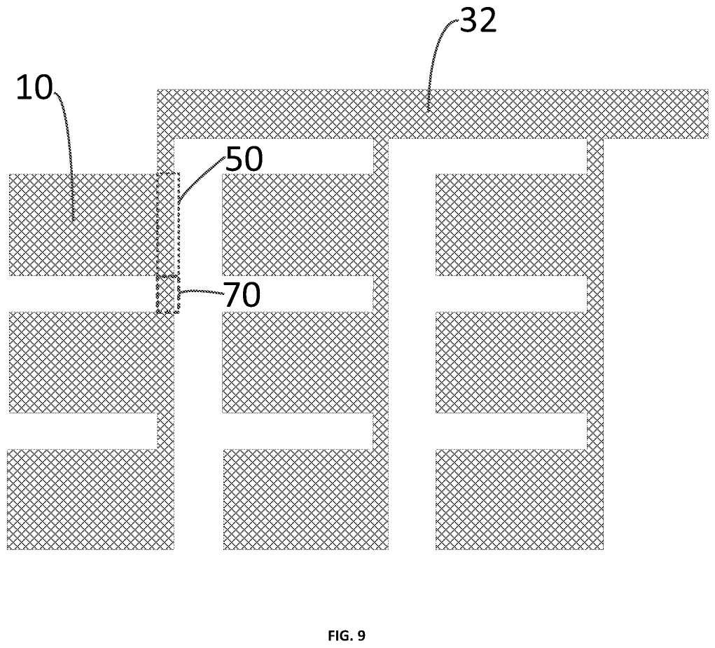

In specific implementation, in the above vibration panel provided by the embodiments of the present disclosure, as shown in FIG. 6 to FIG. 9, the number of piezoelectric devices can be multiple. FIG. 6 to FIG. 8 are a schematic diagram of the bottommost electrode layer 10 in each piezoelectric device. FIG. 9 is a schematic diagram of any layer above the bottommost electrode layer 10 in each piezoelectric device. The multiple piezoelectric devices are arranged in an array, which can prevent the problem of overall failure caused by short circuits in some piezoelectric devices.

In specific implementation, in the above vibration panel provided by the embodiments of the present disclosure, as shown in FIG. 6 to FIG. 9, the vibration panel further includes a first signal line 31 electrically connected to a first conductive part 40, and a second signal line 32 electrically connected to a second conductive part 50. In specific implementation, the inverse piezoelectric effect is utilized to input a first signal through the first signal line 31 to the electrode layers 10 located in odd-numbered layers. For example, the first signal is a ground signal. A second signal is input through the second signal line 32 to the electrode layers 20 located in even-numbered layers. For example, the second signal is a high-frequency AC voltage signal. Thus, an electric field is formed between the electrode layers 10 located in odd-numbered layers and the electrode layers 20 located in even-numbered layers. Each piezoelectric layer 30 generates high-frequency vibration under the action of the electric field, and laser can be used to measure vibration displacement.

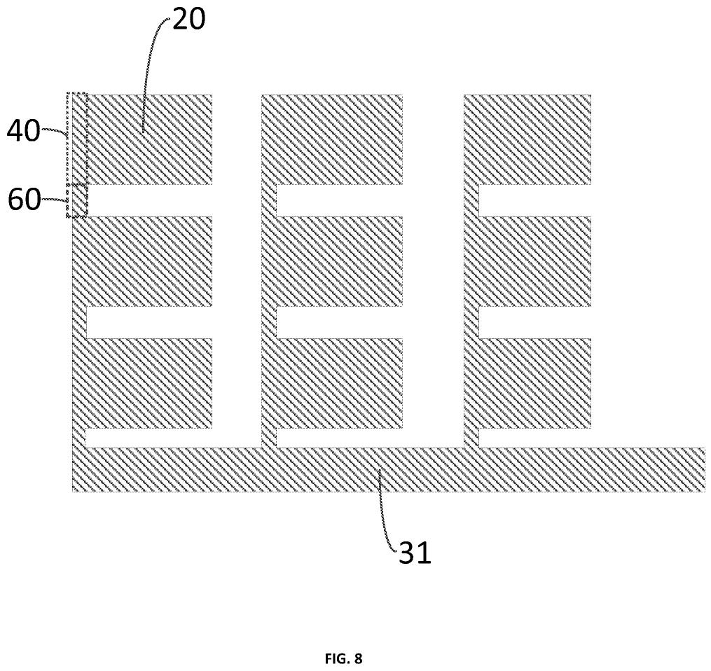

In a possible implementation, as shown in FIG. 6 and FIG. 7, both the first signal line 31 and the second signal line 32 are arranged in the same layer as a bottommost electrode layer 10. In this way, it is only necessary to change the original composition pattern when forming the bottommost electrode layer 10, and the pattern of the first signal line 31, second signal line 32, and bottommost electrode layer 10 can be formed through a one-time composition process. There is no need to add a separate process for preparing the first signal line 31 and second signal line 32, which can simplify the preparation process, save production costs, and improve production efficiency.

During specific implementation, as shown in FIG. 6, a first isolation part 21 and a second isolation part 22 (not shown in FIG. 6) are provided between the electrode layer 10 located in an odd-numbered layer and the second conductive part 50, so as to prevent the short circuit between the positive and negative signals. In order to achieve a better in-plane positive and negative signal isolation effect, in a possible implementation, as shown in FIG. 8, the first signal line 31 is arranged in the same layer as the bottommost electrode layer 10. As shown in FIG. 9, the second signal line 32 is arranged in a different layer from the bottommost electrode layer 10. The second signal line 32 can be arranged in any electrode layer (10 or 20) above the bottommost electrode layer 10. That is, the first signal line 31 in FIG. 8 is located in the bottommost layer, and the second signal line 32 in FIG. 9 is located in any electrode layer (10 or 20) above the bottommost electrode layer 10. The first signal line 31 for inputting the first signal to the electrode layer 10 located in an odd-numbered layer and the second signal line 32 for inputting the second signal to the electrode layer 20 located in an even-numbered layer are designed in different layers, so that the vertical plane isolation of positive and negative signals can be realized, that is, it can realize the effective isolation of positive and negative signals, and avoid problems such as short circuit and crosstalk of positive and negative signals.

In specific implementation, in the above vibration panel provided by the embodiments of the present disclosure, as shown in FIG. 6, first conductive parts 40 of all the piezoelectric devices are electrically connected to a same first signal line 31, and second conductive parts 50 of all the piezoelectric devices are electrically connected to a same second signal line 32. That is, all electrode layers 10 located in odd-numbered layers are electrically connected to the same first signal line 31, and all electrode layers 20 located in even-numbered layers are electrically connected to the same second signal line 32. In this way, the wiring space in the vibration panel can be saved, and the manufacturing process of wiring can be reduced.

In specific implementation, in the above vibration panel provided by the embodiments of the present disclosure, as shown in FIG. 6, among the piezoelectric devices located in the same column, the first conductive parts 40 of two adjacent piezoelectric devices are electrically connected through a third conductive part 60, and the third conductive part 60 is arranged in the same layer as a bottommost electrode layer 10. In this way, it is only necessary to change the original composition pattern when forming the bottommost electrode layer 10, and the pattern of the third conductive part 60 and the bottommost electrode layer 10 can be formed through a one-time composition process. There is no need to add a separate process for preparing the third conductive part 60, which can simplify the preparation process, save production costs, and improve production efficiency.

In specific implementation, in the above vibration panel provided by the embodiments of the present disclosure, as shown in FIG. 6, among the piezoelectric devices located in the same column, the second conductive parts 50 of two adjacent piezoelectric devices are electrically connected through a fourth conductive part 70, and the fourth conductive part 70 is arranged in the same layer as the bottommost electrode layer 10. In this way, it is only necessary to change the original composition pattern when forming the bottommost electrode layer 10, and the pattern of the fourth conductive part 70 and the bottommost electrode layer 10 can be formed through a one-time composition process. There is no need to add a separate process for preparing the fourth conductive part 70, which can simplify the preparation process, save production costs, and improve production efficiency.

In specific implementation, when the first signal line 31 and the second signal line 32 shown in FIG. 6 are designed to be located at the bottommost electrode layer 10, in order to achieve better isolation effect within the positive and negative signal planes, in the vibration panel provided by the embodiments of the present disclosure, as shown in FIG. 7, each piezoelectric layer only exposes the first conductive part 40, the second conductive part 50, the third conductive part 60, the fourth conductive part 70, the first signal line 31, and the second signal line 32. The subsequent production of piezoelectric layer 30 will cover the blank area and electrode layer 10 in FIG. 4.

It should be noted that in order to clearly illustrate the filling of the blank area in FIG. 4 by the piezoelectric layer 30, FIG. 7 does not show the piezoelectric layer 30 covering each electrode layer 10. In actual production, the piezoelectric layer 30 is covered above each electrode layer 10.

In specific implementation, FIGS. 6 to 9 are illustrated by taking the following as an example: all electrode layers 10 located in odd-numbered layers are electrically connected to the same first signal line 31, and all electrode layers 10 located in even-numbered layers are electrically connected to the same second signal line 32. Of course, in the above vibration panel provided by the embodiments of the present disclosure, the first conductive parts of each of the piezoelectric devices can be electrically connected to first signal lines that are independent of each other, and the second conductive parts of each of the piezoelectric devices can be electrically connected to second signal lines that are independent of each other. This can individually control the vibration generated by each piezoelectric component, achieving the function of local vibration.

In specific implementation, in the above vibration panel provided by the embodiments of the present disclosure, when the first conductive parts of each piezoelectric device are respectively electrically connected to mutually independent first signal lines and the second conductive parts of each piezoelectric device are respectively electrically connected to mutually independent second signal lines, the first conductive parts of two adjacent piezoelectric devices in the same column of piezoelectric devices are independent of each other, and the second conductive parts of two adjacent piezoelectric devices in the same column of piezoelectric devices are independent of each other. When the first signal line and the second signal line are both arranged in the same layer as the electrode layer at the bottom, in order to better achieve in-plane positive and negative isolation, the subsequent production of each piezoelectric layer can only expose the first conductive part, second conductive part, first signal line, and second signal line.

In specific implementation, in the above vibration panel provided by the embodiments of the present disclosure, as shown in FIGS. 6 to 9, the first signal line 31 and the second signal line 32 are located on opposite sides of the piezoelectric devices distributed in an array. In this way, the first signal line 31 and the second signal line 32 can be further effectively isolated, and the problem of more wiring on one side of the vibration panel can be prevented.

Based on the same inventive concept, an embodiment of the present disclosure further provides a haptic feedback apparatus, including the above vibration panel provided by the embodiments of the present disclosure. Since the problem-solving principle of the haptic feedback apparatus is similar to that of the aforementioned vibration panel, the implementations of the haptic feedback apparatus can refer to the implementations of the aforementioned vibration panel, and the repetition will not be repeated. The haptic feedback apparatus may be any product or component with display or touch function, such as a mobile phone, a tablet computer, a television, a display, a notebook computer, a digital photo frame, a navigator, and the like.

During specific implementation, the above haptic feedback apparatus provided by the embodiments of the present disclosure may also include other film layers well known to those skilled in the art, which will not be described in detail here.

During specific implementation, the haptic feedback apparatus can determine the touch position of the human body, thereby generating corresponding vibration waveforms, amplitudes and frequencies, and thus human-computer interaction can be realized. Of course, the haptic feedback apparatus can also be applied in fields such as medical treatment, automotive electronics, and motion tracking systems according to actual needs, which will not be described in detail here.

The embodiments of the present disclosure provide a piezoelectric device, a vibration panel, and a haptic feedback apparatus, which is equivalent to sharing an electrode layer for inputting a first signal between two adjacent piezoelectric layers, and two voltage layers outside the two adjacent piezoelectric layers are electrically connected, to input the same second signal. In this way, the piezoelectric device is equivalent to at least two piezoelectric structures arranged in parallel, and the intensity of the haptic feedback of each piezoelectric layer in the parallel structures can be superimposed. Therefore, compared with the related art in which in order to increase the intensity of the haptic feedback, a thicker piezoelectric layer is set, which leads to the problem of high driving voltage in the related art, in the embodiments of the present disclosure, if the same intensity of the haptic feedback is needed to achieve as in the related art, the sum of the thicknesses of each piezoelectric layer is only equal to the thickness of one entire layer in the related art. For example, there are four piezoelectric layers, the corresponding input driving voltage of each piezoelectric layer can be reduced to a quarter of that in the related art. Therefore, the piezoelectric device provided by the embodiments of the present disclosure adopts at least two piezoelectric layers, and the driving voltage of the piezoelectric device can be reduced on the basis of improving the intensity of the haptic feedback of the piezoelectric device.

While preferred embodiments of the present disclosure have been described, additional changes and modifications can be made to these embodiments by those skilled in the art once the basic inventive concept is appreciated. Therefore, it is intended that the appended claims be construed to cover the preferred embodiments and all changes and modifications which fall within the scope of the present disclosure.

Obviously, those skilled in the art can make various changes and modifications to the embodiments of the present disclosure without departing from the spirit and scope of the embodiments of the present disclosure. In this way, if these modifications and variations of the embodiments of the present disclosure fall within the scope of the claims of the present disclosure and equivalent technologies thereof, the present disclosure is also intended to include these modifications and variations.

1. A piezoelectric device, comprising: at least three electrode layers alternately stacked, and a piezoelectric layer between every two adjacent electrode layers; wherein
for all the electrode layers, the electrode layers located in odd-numbered layers are electrically connected to each other, the electrode layers located in even-numbered layers are electrically connected to each other, and the electrode layers located in odd-numbered layers are insulated from the electrode layers located in even-numbered layers.

2. The piezoelectric device according to claim 1, further comprising a first conductive part and a second conductive part extending along a thickness direction of the piezoelectric device, the first conductive part and the second conductive part are arranged on opposite sides of the piezoelectric layer; wherein
the electrode layers located in odd-numbered layers are electrically connected through the first conductive part, and the electrode layers located in even-numbered layers are electrically connected through the second conductive part.

3. The piezoelectric device according to claim 2, wherein there is a first gap between the electrode layers located in odd-numbered layers and the second conductive part have, and there is a second gap between the electrode layers located in even-numbered layers and the first conductive part;
the piezoelectric device further comprises: a first isolation part filled in the first gap, and a second isolation part filled in the second gap.

4. The piezoelectric device according to claim 3, wherein materials of the first isolation part and the second isolation part are the same as a material of the piezoelectric layers, and each of the piezoelectric layers is sequentially connected in series through the first isolation part and the second isolation part.

5. The piezoelectric device according to claim 1, wherein a total number of the electrode layers and the piezoelectric layers are 5 to 21 layers.

6. The piezoelectric device according to claim 1, wherein each of the electrode layers comprises approximately the same thickness, and each of the piezoelectric layers comprises approximately the same thickness.

7. The piezoelectric device according to claim 6, wherein a thickness of each of the electrode layers ranges from 100 nm to 200 nm, and a thickness of each of the piezoelectric layers ranges from 1.5 μm to 2 μm.

8. A vibration panel, comprising the piezoelectric device according to claim 1.

9. The vibration panel according to claim 8, further comprising: a first signal line electrically connected to a first conductive part, and a second signal line electrically connected to a second conductive part; wherein
the first signal line and the second signal line are arranged in a layer same as a layer where a bottommost electrode layer is;
or, the first signal line is arranged in a layer same as a layer where a bottommost electrode layer is, and the second signal line is arranged in a layer different from the layer where the bottommost electrode layer is.

10. The vibration panel according to claim 9, wherein the vibration panel comprises a plurality of the piezoelectric devices, and the piezoelectric devices are distributed in an array.

11. The vibration panel according to claim 10, wherein first conductive parts of all the piezoelectric devices are electrically connected to a same first signal line, and second conductive parts of all the piezoelectric devices are electrically connected to a same second signal line.

12. The vibration panel according to claim 11, wherein among the piezoelectric devices located in a same column, the first conductive parts of two adjacent piezoelectric devices are electrically connected through a third conductive part, and the third conductive part is arranged in a layer same as a layer where a bottommost electrode layer is.

13. The vibration panel according to claim 12, wherein among the piezoelectric devices located in the same column, the second conductive parts of two adjacent piezoelectric devices are electrically connected through a fourth conductive part, and the fourth conductive part is arranged in a layer same as the layer where the bottommost electrode layer is.

14. The vibration panel according to claim 13, wherein each of the piezoelectric layers exposes only the first conductive part, the second conductive part, the third conductive part, the fourth conductive part, the first signal line and the second signal line.

15. The vibration panel according to claim 10, wherein the first conductive parts of each of the piezoelectric devices are electrically connected to first signal lines independent from each other, and the second conductive parts of each of the piezoelectric devices are electrically connected to second signal lines independent from each other.

16. The vibration panel according to claim 15, wherein each of the piezoelectric layers exposes only the first conductive part, the second conductive part, the first signal line, and the second signal line.

17. The vibration panel according to claim 9, wherein the first signal line and the second signal line are located on opposite sides of the piezoelectric devices distributed in an array.

18. A haptic feedback apparatus, comprising the vibration panel according to claim 8.
